(19) United States
(12) Patent Application Publication
(10) Pub. No.: US 2024/0321574 A1
(43) Pub. Date: Sep. 26, 2024

(54) METHOD AND DEVICE FOR PRODUCING A LOW-DEFECT INTERFACE

(71) Applicant: Robert Bosch GmbH, Stuttgart (DE)

(72) Inventors: Mirjam Henn, Ditzingen (DE); Christian Huber, Ludwigsburg (DE); Jens Baringhaus, Sindelfingen (DE)

(21) Appl. No.: 18/587,221

(22) Filed: Feb. 26, 2024

(30) Foreign Application Priority Data
Feb. 27, 2023 (DE) 10 2023 201 756.3

(51) Int. Cl. H01L 21/02; H01L 21/67; H01L 29/20

(52) U.S. Cl. CPC H01L 21/02312; H01L 21/02307; H01L 21/6704; H01L 21/67098; H01L 29/2003

(57) ABSTRACT

A method for producing a low-defect interface between a GaN semiconductor substrate and a gate dielectric of a GaN power transistor. The method includes: introducing at least one GaN semiconductor substrate into a device; generating a vacuum within the device; heating the device to a first temperature; performing a first temperature step at the first temperature, wherein a reactive medium is introduced into the device and has a first partial pressure; performing a second temperature step at a second temperature, wherein an inert medium is introduced into the device and has a second partial pressure, and generating the gate dielectric on the GaN semiconductor substrate.

### FIELD

The present invention relates to a method and a device for producing a low-defect interface.

### BACKGROUND INFORMATION

Power transistors made of gallium nitride have a high breakdown field strength. A typical power transistor is a MOSFET which generates an inversion channel in the semiconductor material by applying a gate voltage to a metal-insulator semiconductor junction. In this case, the inversion channel forms a few nanometers below the interface between the gate dielectric and the p-doped regions. On said interface, various defects can occur, which have a negative effect on the channel mobility since these defects scatter, or deflect, and capture the minority charge carriers of the inversion channel so that the minority charge carriers can no longer contribute to the current flow. An example of defects are the undesired incorporation of impurity atoms. The main source thereof is surface contamination of the p-doped regions or inadequate cleaning of the surface prior to the deposition of the gate dielectric. A further example of defects are electronic states at the GaN surface, which are caused by insufficient saturation of free bonds. A disadvantage in the case of both types of defects is that processes carried out afterwards, i.e., after the deposition of the gate dielectric, such as high-temperature methods, can neither remove nor eliminate the defects.

An object of the present invention is to overcome this disadvantage.

### SUMMARY

A method according to an example embodiment of the present invention for producing a low-defect interface between a GaN semiconductor substrate and a gate dielectric of a GaN power transistor comprises introducing at least one GaN semiconductor substrate into a device and generating a vacuum within the device. The method furthermore comprises heating the device to a first temperature. Furthermore, the method comprises performing a first temperature step at the first temperature, wherein a reactive medium is introduced into the device and has a first partial pressure, and performing a second temperature step at a second temperature, wherein an inert gas is introduced into the device and has a second partial pressure. The method furthermore comprises generating the gate dielectric on the GaN semiconductor substrate.

In other words, prior to the application of the dielectric layer or the gate dielectric, the GaN surface of the GaN semiconductor substrate is cleaned by means of a two-stage in-situ annealing method so that a particularly pure and low-defect GaN surface of the semiconductor substrate is present immediately prior to the application and is retained until the dielectric layer or the gate dielectric is applied. The method is carried out within the same device without interrupting the vacuum. A low-defect GaN surface comprises contamination elements, such as fluorine or chlorine, in an order of magnitude of less than 1E08 at/cm².

An advantage here is that contaminations on the GaN surface can be removed in a simple manner. In addition, unsaturated bonds on the GaN surface can be saturated. Furthermore, residues of impurity atoms which may originate from previous process steps are removed gently.

In one embodiment of the present invention, nitrogen is introduced into the device during the heating.

It is advantageous here that loss of nitrogen of the GaN semiconductor substrate can be counteracted.

In a development of the present invention, the GaN semiconductor substrate is wet-chemically cleaned before being introduced into the device.

It is advantageous here that a rough preliminary cleaning of the GaN surface takes place, wherein, for example, native gallium oxide is removed, which grows with low quality on the GaN surface when the semiconductor substrate is exposed to air for a while.

In a development of the present invention, the first temperature is lower than the decomposition temperature of the GaN, wherein the first temperature is in particular in the range between 650° C. and 800° C.

It is advantageous here that the contamination elements are efficiently desorbed without decomposition of the GaN surface.

In a further embodiment of the present invention, the first temperature is lower than the second temperature.

An advantage here is that the first temperature step is energy-efficient.

In a development of the present invention, the first partial pressure and the second partial pressure each have a value between 0.01 mbar and 1 bar, wherein the first partial pressure is lower than the second partial pressure.

It is advantageous here that the desorption of the contamination elements is optimally supported in the first temperature step, and the decomposition of the GaN surface in the second temperature step is efficiently counteracted.

In a further embodiment of the present invention, the reactive medium comprises NH₃, N₂O or NO.

An advantage here is that the supply of nitrogen, in particular reactive nitrogen in the case of NH₃ or NO, shifts the decomposition temperature of GaN to higher temperatures so that a higher first temperature can be used. A further advantage of the reactive medium is that the surface can thereby be cleaned more efficiently than by an inert medium.

In a development of the present invention, the inert medium comprises N₂, Ar, He, Xe or Kr.

It is advantageous here that, in particular, the nitrogen partial pressure can counteract the decomposition of GaN.

A device for producing a low-defect interface between a GaN semiconductor substrate and a gate dielectric of a GaN power transistor according to an example embodiment of the present invention comprises at least one chamber into which at least one GaN semiconductor substrate can be introduced, wherein a vacuum can be generated within the chamber; a heating device, wherein the heating device is configured to set various temperatures in the range between 500° C. and 1500° C.; and a control unit.

According to an example embodiment of the present invention, a supply device is mechanically connected to the at least one chamber, wherein the control unit is configured to control the supply device in order to introduce reactive media and inert media into the at least one chamber, and the at least one chamber and the supply device withstand pressures in the range between 0.01 mbar to 1 bar, wherein the control unit is configured to control a generation of the gate dielectric.

An advantage here is that the GaN surface cleaning takes place in situ.

In a development of the present invention, the device has two chambers.

It is advantageous here that the method steps at low pressures can be carried out in one chamber, e.g., first temperature step and deposition of the dielectric layer, and the method steps at higher pressures, such as atmospheric pressure, can be carried out in the other chamber, e.g., the second temperature step, the heating and the cooling.

Further advantages can be found in the following description of exemplary embodiments and in the rest of the disclosure herein.

### BRIEF DESCRIPTION OF THE DRAWINGS

The present invention is explained below with reference to preferred embodiments and the figures.

FIG. 1 shows a method for producing a low-defect interface between a GaN semiconductor substrate and a gate dielectric of a GaN power transistor.

FIG. 2 shows a device for producing a low-defect interface between a GaN semiconductor substrate and a gate dielectric of a GaN power transistor.

### DETAILED DESCRIPTION OF EXAMPLE EMBODIMENTS

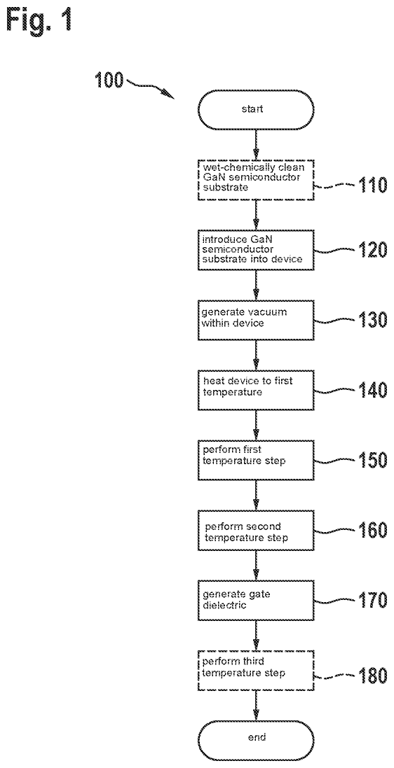

FIG. 1 shows a method 100 for producing a low-defect interface between a GaN semiconductor substrate and a gate dielectric of a GaN power transistor. The method starts with a step 120, in which at least one GaN semiconductor substrate is introduced into a device. The GaN semiconductor substrate already has at least one drift layer and p-doped regions. In a following step 130, a vacuum is generated within the device. In a following step 140, the device is heated to a first temperature. The first temperature is the process temperature of a first temperature step, which is carried out in the following step 150. During heating, the device can have a nitrogen partial pressure in order to counteract the loss of nitrogen of the GaN surface of the GaN semiconductor substrate, wherein the nitrogen partial pressure has a value between 0.01 mbar and 1 bar. In step 150, the first temperature step is performed at the first temperature, wherein a reactive medium is introduced into the device and has a first partial pressure. This means that a first in-situ annealing takes place at a first temperature, or the process temperature, in a reactive atmosphere. The reactive medium reacts with the foreign elements adsorbed on the GaN surface to form volatile species, which can desorb from the surface at the process temperature. This chemical thermal reaction primarily makes it possible to remove oxygen, carbon or hydrocarbon contaminations. It should be noted that, without atomic species of the reactive medium, e.g., atomic nitrogen and hydrogen when using a NH₃ atmosphere, higher energies or temperatures would be necessary in order to be able to break up the corresponding bonds of Ga and N with the contamination elements and to subsequently be able to remove the contamination elements. These temperatures would be above the decomposition temperature of GaN and would damage the GaN surface. NH₃, N₂O, NO, O₂, H₂ or a combination of NH₃ and N₂ are, for example, used as the reactive medium. After step 150 has been carried out, residues of the reactive medium generally remain on the GaN surface. A second temperature step with a second temperature is therefore performed in a following step 160, wherein an inert medium is introduced into the device and has a second partial pressure. This means that a second in-situ annealing takes place at a second temperature, or the process temperature of the second temperature step, in an inert atmosphere. The residues of the reactive medium are, for example, removed by desorption. What remains is a cleaned GaN surface suitable for forming a low-defect interface to a subsequently deposited gate dielectric. N₂, Ar, He, Xe or Kr can, for example, be used as inert medium. If a hydrogen-containing reactive medium was used in the first temperature step, the hydrogen diffused through the GaN surface into the drift layer and/or the p-doped region is additionally expelled in step 160.

In a following step 170, the gate dielectric is, for example, generated by means of LPCVD on the GaN semiconductor substrate, wherein the GaN semiconductor substrate has at least one drift layer and p-doped regions.

In other words, the method 100 according to the present invention is a two-stage in-situ annealing method which is carried out in the same device before depositing a gate dielectric. During the method steps, the semiconductor substrate to be processed is thus located within the device and is not exposed to the air.

In a following optional step 180, a third temperature step can be performed at a third temperature. The third temperature is preferably in a temperature range of 600° C. to 1000° C. N₂ at a partial pressure of 0.01 mbar to 1 bar is, for example, used as the medium. This is a post-deposition annealing. In this case, the dielectric layer, or the gate dielectric, deposited in step 170 can be compressed, undesired volatile species, such as hydrogen, can be diffused out of the gate dielectric and the GaN, bonds at the interface between GaN and the gate dielectric can be changed, or a thin high-quality GaO intermediate layer can be generated at the interface between GaN and the gate dielectric. This improves the properties of the power transistor in the conductive state and in the blocking state. The semiconductor substrate to be processed preferably remains in the device between steps 170 and optional step 180. This means that the semiconductor substrate to be processed is not exposed to air. In order to produce a GaN power transistor, the front side of the power transistor and the rear side process are subsequently processed according to the related art.

In a development, a step 110, in which the GaN semiconductor substrate is wet-chemically cleaned, can be carried out before step 120. The wet-chemical cleaning media comprise, for example, hydrochloric acid or hydrofluoric acid or another acid. Alternatively, an alkaline cleaning medium, such as tetramethylammonium hydroxide or an ammonia solution can be used. This process step is performed ex situ, i.e., outside the device, and results in a rough preliminary cleaning of the GaN surface. In doing so, native gallium oxide, which forms in low quality on the GaN surface when the GaN semiconductor substrate comes into contact with air, is removed, for example. The materials remaining on the surface during this cleaning step, such as fluorine, chlorine, or carbon, are subsequently removed in situ by means of the first temperature step.

In one exemplary embodiment, the first temperature, or the process temperature of the first temperature step, can have a temperature range between 650° C. and 800° C. In this case, the process temperature is low and is below the decomposition temperature of GaN so that efficient desorption of the contamination elements can be carried out without loss of nitrogen of the GaN surface.

In a further exemplary embodiment, the first temperature is above 800° C.; in particular, the first temperature may have a value of up to 1500° C. To this end, the reactive medium must comprise a nitrogen-containing compound, i.e., for example, NH₃, N₂O, NO or a combination of NH₃ and N₂. The second temperature can have the same temperature range as the first temperature. Alternatively, the second temperature has a higher value.

The first partial pressure preferably comprises low pressure but can also be atmospheric pressure. The second partial pressure is preferably atmospheric pressure.

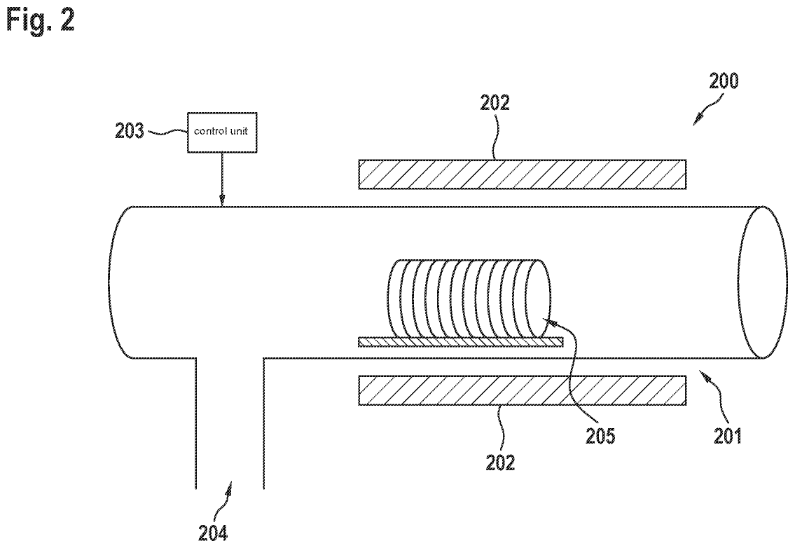

FIG. 2 shows a device 200 for producing a low-defect interface between a GaN semiconductor substrate and a gate dielectric of a GaN power transistor with at least one chamber 201, a heating device 202, a control unit 203, and a supply device 204. At least one GaN semiconductor substrate or GaN semiconductor wafer 205 can be introduced into the chamber 201, wherein the GaN semiconductor substrate has at least one drift layer and p-doped regions. A vacuum can be generated within the chamber 201. The heating device 202 is configured to set various temperatures in the range between 500° C. and 1500° C. The control unit 203 controls the annealing steps, the temperature ramps and an LPCVD system, which generates the gate dielectric. This means that temperature, pressure, and gases are controlled in a time-dependent manner via the control unit 203. By means of the supply device 204, both reactive media and inert media can be introduced into the chamber 201. The chamber 201 and the supply device 204 withstand pressures in the range of 0.01 mbar to 1 bar. The device 200 cleans the GaN semiconductor substrate within the chamber 201 in situ and generates the gate dielectric on the GaN semiconductor substrate. This means that the device 200 is a modified LPCVD system, which withstands pressures up to atmospheric pressure within the system, wherein a two-stage in-situ cleaning method is carried out before a dielectric layer or the gate dielectric is deposited.

In one exemplary embodiment, the device 200 has two chambers 201 connected to one another with tubes. The first annealing step is preferably carried out at negative pressure or low pressure in the first chamber, and the second annealing step is preferably carried out at atmospheric pressure in the second chamber. The LPCVD step is carried out in the first chamber without the vacuum having to be interrupted. In addition, the post-deposition annealing could be carried out in the second chamber.

The two-stage annealing method and the device can be used in the production of GaN MOSFETs of any type, i.e., besides vertical MOSFETs with a planar gate, also in lateral MOSFETs or trench MOSFETs. Due to the low-defect interface between the drift layer, the p-doped regions and the gate dielectric, the power transistors or MOSFETs produced in this way all have very high channel mobility.

A GaN power transistor comprising a defect-low interface produced in this way between the GaN semiconductor substrate and the gate dielectric by means of this device is used in the electrical drive train of an electrical or a hybrid vehicle, e.g., in a DC/DC converter or inverter, and in vehicle charging devices.

1-10. (canceled)

11. A method for producing a low-defect interface between a GaN semiconductor substrate and a gate dielectric of a GaN power transistor, comprising the following steps:
introducing at least one GaN semiconductor substrate into a device;
generating a vacuum within the device;
heating the device to a first temperature;
performing a first temperature step at the first temperature, wherein in the first temperature step, a reactive medium is introduced into the device and has a first partial pressure;
performing a second temperature step at a second temperature, wherein in the second temperature step, an inert medium is introduced into the device and has a second partial pressure; and
generating the gate dielectric on the GaN semiconductor substrate.

12. The method according to claim 11, wherein nitrogen is introduced into the device during the heating.

13. The method according to claim 11, wherein the GaN semiconductor substrate is wet-chemically cleaned before being introduced into the device.

14. The method according to claim 11, wherein the first temperature is lower than a decomposition temperature of the GaN, wherein the first temperature is in a range between 650° C. and 800° C.

15. The method according to claim 11, wherein the first temperature is lower than the second temperature.

16. The method according to claim 11, wherein the first partial pressure and the second partial pressure each have a value between 0.01 mbar and 1 bar, wherein the first partial pressure is lower than the second partial pressure.

17. The method according to claim 11, wherein the reactive medium includes NH₃ or N₂O or NO.

18. The method according to claim 11, wherein the inert medium includes N₂ or Ar or He or Xe or Kr.

19. A device for producing a low-defect interface between a GaN semiconductor substrate and a gate dielectric of a GaN power transistor, the device comprising:
at least one chamber into which at least one GaN semiconductor substrate can be introduced, and wherein a vacuum can be generated within the chamber;
a heating device configured to set various temperatures in a range between 500° C. and 1500° C.;
a control unit; and
a supply device mechanically connected to the at least one chamber, wherein the control unit is configured to control the supply device to introduce reactive media and inert media into the at least one chamber, wherein the at least one chamber and the supply device can withstand pressures in a range between 0.01 mbar to 1 bar, and the control unit is configured to control a generation of the gate dielectric.

20. The device according to claim 19, wherein the device has two chambers.
